(19) United States
(12) Patent Application Publication
(10) Pub. No.: US 2024/0298429 A1
(43) Pub. Date: Sep. 5, 2024

(54) FOLDABLE DISPLAY BACK PANEL AND DISPLAY TERMINAL

(71) Applicant: WUHAN CHINA STAR OPTOELECTRONICS SEMICONDUCTOR DISPLAY TECHNOLOGY CO., LTD., Wuhan,Hubei (CN)

(72) Inventor: Rongkun CHEN, Wuhan (CN)

(73) Assignee: WUHAN CHINA STAR OPTOELECTRONICS SEMI CONDUCTOR DISPLAY TECHNOLOGY CO., LTD., Wuhan (CN)

(21) Appl. No.: 17/615,117

(22) PCT Filed: Nov. 8, 2021
(86) PCT No.: PCT/CN2021/129279

§ 371 Date: May 9, 2024

(30) Foreign Application Priority Data
Sep. 29, 2021 (CN) 202111153986.2

(51) Int. Cl. H05K 7/20

(52) U.S. Cl. CPC H05K 7/20963

(57) ABSTRACT

The present disclosure provides a foldable display back panel and a display terminal. The foldable display back panel includes a rigid support layer and a heat dissipation layer disposed on the rigid support layer. The rigid support layer includes a first planar portion, a second planar portion, and a bending portion. The heat dissipation layer includes a first heat dissipation portion, a second heat dissipation portion, and a bridging portion respectively located on the first planar portion, the second planar portion, and the bending portion. The bridging portion includes a plurality of first thermally conductive members spaced apart from each other and connected to the first heat dissipation portion and the second heat dissipation portion.

### FIELD OF INVENTION

The present disclosure relates to the display field, and in particular, to a foldable display back panel and a display terminal.

### BACKGROUND OF INVENTION

Currently, for heat dissipation, a foldable screen requires a graphite material to be attached to a back of a rigid support layer as a heat dissipation layer. However, if the graphite heat dissipation layer is folded in a bending region, a multi-layer flake structure of the graphite is easily delaminated, and the delaminated and cracked graphite causes surface wrinkles. Therefore, display defects, such as imprints, may be observed on the screen from a front side. If the graphite heat dissipation layer is snapped in the bending region to avoid folding, the graphite on two sides of the bending region cannot be connected, resulting in degrade of the heat conducting performance.

### SUMMARY OF INVENTION

### Technical Problem

In the conventional foldable screen, when the graphite heat dissipation layer is folded, display defects, such as imprints easily occur. However, when the graphite heat dissipation layer avoids folding, the heat conducting performance caused is degraded.

### Technical Solution

The present disclosure provides a foldable display back panel and a display terminal, to alleviate the technical problem that the conventional foldable display back panel cannot achieve both desirable heat conducting performance and display effects.

In order to resolve the foregoing technical problems, the present disclosure provides the following technical solutions.

The present disclosure provides a foldable display back panel. The foldable display back panel includes:
a rigid support layer including a first planar portion, a second planar portion, and a bending portion located between the first planar portion and the second planar portion; and
a heat dissipation layer disposed on the rigid support layer and including a first heat dissipation portion located on the first planar portion, a second heat dissipation portion located on the second planar portion, and a bridging portion located on the bending portion.

The bridging portion includes a plurality of first thermally conductive members spaced apart from each other and connected to the first heat dissipation portion and the second heat dissipation portion.

In the foldable display back panel of the present disclosure, the first thermally conductive members are disposed in a first direction.

In the foldable display back panel of the present disclosure, the plurality of first thermally conductive members are equidistantly arranged in a second direction.

In the foldable display back panel of the present disclosure, the second direction is an extending direction of the bending portion, and the first direction is perpendicular to the second direction.

In the foldable display back panel of the present disclosure, in the first direction, a length of each of the first thermally conductive members is greater than a length of the bending portion.

In the foldable display back panel of the present disclosure, in the first direction, the length of the bending portion accounts for 8% to 11% of a length of the heat dissipation layer.

In the foldable display back panel of the present disclosure, at least one notch is provided on the first heat dissipation portion and/or the second heat dissipation portion.

In the foldable display back panel of the present disclosure, the notch is located at an end corner of the corresponding heat dissipation portion.

In the foldable display back panel of the present disclosure, the bridging portion further includes a plurality of second thermally conductive members.

In the foldable display back panel of the present disclosure, the plurality of second thermally conductive members are spaced apart from each other.

In the foldable display back panel of the present disclosure, the first thermally conductive members and the second thermally conductive members intersect each other.

In the foldable display back panel of the present disclosure, the first thermally conductive members, the second thermally conductive members, the first heat dissipation portion, and the second heat dissipation portion are integrally formed.

In the foldable display back panel of the present disclosure, the foldable display back panel further includes a first protective layer and a second protective layer disposed on two sides of the heat dissipation layer.

In the foldable display back panel of the present disclosure, the first protective layer and the second protective layer are consecutively disposed on the heat dissipation layer and cover the bridging portion.

In the foldable display back panel of the present disclosure, the first protective layer and the second protective layer are elastic buffer layers.

In the foldable display back panel of the present disclosure, the first protective layer is disposed between the rigid support layer and the heat dissipation layer.

In the foldable display back panel of the present disclosure, side surfaces of the first protective layer in contact with the rigid support layer and the heat dissipation layer are coated with a first adhesive layer.

In the foldable display back panel of the present disclosure, the second protective layer is disposed on a side surface of the heat dissipation layer away from the rigid support layer.

In the foldable display back panel of the present disclosure, a side surface of the second protective layer in contact with the heat dissipation layer is coated with a second adhesive layer.

The present disclosure further provides a display terminal. The display terminal includes a terminal body and the above foldable display back panel. The terminal body and the foldable display back panel are combined as a whole.

### Beneficial Effects

According to the present disclosure, the heat dissipation layer is disposed on the rigid support layer to improve the heat dissipation capability of the foldable display back panel. The bridging portion of the heat dissipation layer corresponds to the bending portion of the rigid support layer. The bridging portion includes the plurality of first thermally conductive members spaced apart from each other. Therefore, not only the first heat dissipation portion and the second heat dissipation portion of the heat dissipation layer are connected as a whole, enhancing the heat conducting performance and the heat dissipation performance, but also the plurality of first thermally conductive members spaced apart from each other are more easily bent without wrinkles, reducing the possibility of abnormal display. In this way, both relatively high heat dissipation performance and display quality are achieved.

### BRIEF DESCRIPTION OF DRAWINGS

To describe the technical solutions of the embodiments of the present disclosure more clearly, the following briefly introduces the accompanying drawings required for describing the embodiments. Apparently, the accompanying drawings in the following description show only some embodiments of the present disclosure, and a person skilled in the art may still derive other drawings from these accompanying drawings without creative efforts.

FIG. 1 is a schematic diagram of a first planar structure of a foldable display back panel according to the present disclosure.

FIG. 2 is a schematic diagram of relative positions of a bridging portion and a bending portion according to the present disclosure.

FIG. 3 is a side view of the foldable display back panel according to the present disclosure.

FIG. 4 is a schematic diagram of a second planar structure of the foldable display back panel according to the present disclosure.

FIG. 5 is a schematic diagram of a third planar structure of the foldable display back panel according to the present disclosure.

FIG. 6 is a schematic diagram of a second planar structure of a heat dissipation layer according to the present disclosure.

FIG. 7 is a schematic diagram of a third planar structure of the heat dissipation layer according to the present disclosure.

FIG. 8 is a schematic diagram of a composite structure of the heat dissipation layer, a first protective layer, and a second protective layer according to the present disclosure.

FIG. 9 is a schematic diagram of a fourth planar structure of the foldable display back panel according to the present disclosure.

### REFERENCE NUMERAL DESCRIPTION

Rigid support layer 100, First planar portion 110, Second planar portion 120, Bending portion 130, Heat dissipation layer 200, First heat dissipation portion 210, Second heat dissipation portion 220, Bridging portion 230, First thermally conductive member 231, Second thermally conductive member 232, Notch 240, First protective layer 300, Second protective layer 400, First adhesive layer 500, Second adhesive layer 600, Driving chip IC 700.

### DETAILED DESCRIPTION OF PREFERRED EMBODIMENTS

The following clearly and completely describes the technical solutions in the embodiments with reference to the accompanying drawings in the embodiments of the present disclosure. Apparently, the described embodiments are some exemplary embodiments of the present disclosure and not to be taken in an exhaustive sense. All other embodiments obtained by a person skilled in the art based on the embodiments of the present disclosure without creative efforts shall fall within the protection scope of the present disclosure. In addition, it should be understood that the specific implementations described herein are merely used to describe and explain the present disclosure, but are not intended to limit the present disclosure. In the present disclosure, without the contrary explanation, the directional terms such as “upper” and “lower” usually refers to the top and bottom of the apparatus in an actual use or a working state, and specifically, is the drawing direction of the accompanying drawings. However, “inside and outside” refer to the contour of the apparatus.

For heat dissipation, a foldable screen requires a graphite material to be attached to a back of a rigid support layer as a heat dissipation layer. However, if the graphite heat dissipation layer is folded in a bending region, a multi-layer flake structure of the graphite is easily delaminated, and the delaminated and cracked graphite causes surface wrinkles. Therefore, display defects, such as imprints, may be observed on the screen from a front side. Therefore, currently, the graphite is designed as two separated pieces. The graphite heat dissipation layer is snapped in a bending region without folding, to reduce abnormal display. However, the design of two separated graphite pieces has the following problems. Since a driving chip IC is generally disposed on a side of a display module, a side of the display module close to the driving chip IC has a higher temperature. In addition, since the two graphite pieces are snapped (not connected) in the bending region, the overall heat conducting performance of the heat dissipation layer is reduced. As a result, the overall heat dissipation efficiency of the display module is degraded. The present disclosure provides the following solutions based on the foregoing technical problems.

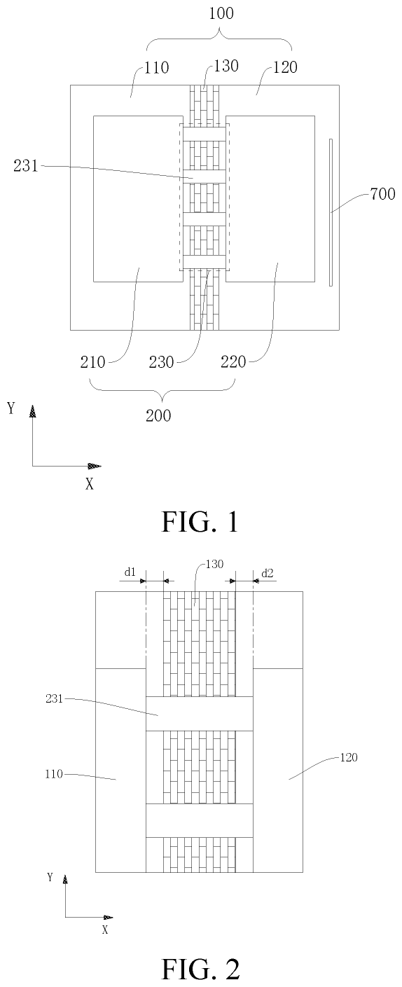

Referring to FIGS. 1 to 9, the present disclosure provides a foldable display back panel. The foldable display back panel includes:
a rigid support layer 100, including a first planar portion 110, a second planar portion 120, and a bending portion 130 located between the first planar portion 110 and the second planar portion 120; and
a heat dissipation layer 200, disposed on the rigid support layer 100. The heat dissipation layer 200 includes a first heat dissipation portion 210 located on the first planar portion 110, a second heat dissipation portion 220 located on the second planar portion 120, and a bridging portion 230 located on the bending portion 130.

The bridging portion 230 includes a plurality of first thermally conductive members 231 spaced apart from each other. The plurality of first thermally conductive members 231 are spaced apart from each other. The first thermally conductive members 231 are connected to the first heat dissipation portion 210 and the second heat dissipation portion 220.

According to the present embodiment, the heat dissipation layer 200 is disposed on the rigid support layer 100 to improve the heat dissipation capability of the foldable display back panel. The bridging portion 230 of the heat dissipation layer 200 corresponds to the bending portion 130 of the rigid support layer 100. The bridging portion 230 includes the plurality of first thermally conductive members 231 spaced apart from each other. Therefore, not only the first heat dissipation portion 210 and the second heat dissipation portion 220 of the heat dissipation layer 200 are connected as a whole, enhancing the heat conducting performance and the heat dissipation performance, but also the plurality of first thermally conductive members 231 spaced apart from each other are more easily bent without wrinkles, reducing the possibility of abnormal display. In this way, both relatively high heat dissipation performance and display quality are achieved.

In the present embodiment, the heat dissipation layer 200 is disposed on a back side of the rigid support layer 100. That is to say, the heat dissipation layer 200 is disposed on a side surface of the rigid support layer 100 away from a display panel (not shown in the figure). A driving chip IC 700 is disposed on a side of the second planar portion 120 away from the first planar portion 110. That is to say, the driving chip IC 700 is disposed close to the second heat dissipation portion 220.

In the present embodiment, the rigid support layer 100 may be made of a metal material or an alloy material having a relatively large rigidness, such as a stainless steel sheet. The bending portion 130 of the rigid support layer 100 may be patterned to form a plurality of hollowed-out portions, to improve the bending performance of the bending portion 130.

In the present embodiment, the heat dissipation layer 200 may be made of metal materials having desirable heat conducting performance and extensibility or an alloy material thereof (such as Al, Cu, or Age), or may be made of an inorganic material (such as graphite or graphene) having desirable heat conducting performance and extensibility.

The technical solutions of the present disclosure are described below with reference to detailed embodiments. It is to be noted that, a description order of the following embodiments is not construed as a limitation on a preferred order of the embodiments.

Referring to FIG. 1, in the foldable display back panel of the present disclosure, the first thermally conductive members 231 are disposed in a first direction X. The plurality of first thermally conductive members 231 are equidistantly arranged in a second direction Y.

The second direction Y is an extending direction of the bending portion 130, and the first direction is perpendicular to the second direction.

In the present embodiment, the first thermally conductive members 231 may be rectangular strips. A length direction of each of the rectangular strips is the first direction X, and a width direction of the rectangular strip is the second direction Y.

In the present embodiment, the rectangular strip-shaped first thermally conductive members 231 are disposed in the first direction X, and the plurality of first thermally conductive members 231 are arranged in the second direction Y, so that the plurality of first thermally conductive members 231 form a uniform and stable bridging structure between the first heat dissipation portion 210 and the second heat dissipation portion 220. Therefore, more efficient heat conduction is achieved between the first heat dissipation portion 210 and the second heat dissipation portion 220. In addition, since the bridging structure can largely relieve the bending stress concentrated in the bending portion 130, the possibility of abnormal display at the bending portion 130 is reduced.

Referring to FIG. 1, in the foldable display back panel of the present disclosure, in the first direction X, a length of each of the first thermally conductive members 231 is greater than a length of the bending portion 130. That is to say, when the rigid support layer 100 is in unfolded, the length of each of the first thermally conductive member 231 in the first direction X is greater than a distance between the first planar portion 110 and the second planar portion 120.

In the present embodiment, two ends of the first thermally conductive member 231 exceeds lines of intersection of the bending portion 130 and the first planar portion 110 and the second planar portion 120, so that the first thermally conductive member 231 can gently extends into the bending portion 130 from the first planar portion 110 or the second planar portion 120.

Although a relatively large stress exists at an intersection of the bending portion 130 and the first planar portion 110 or the second planar portion 120, the first thermally conductive member 231 is prevented from being easily separated from the first heat dissipation portion 210 or the second heat dissipation portion 220 by means of the above arrangement. In this way, a more stable connection and a more stable heat conducting effect are achieved.

In the present embodiment, as shown in FIG. 2, an end portion of the first thermally conductive member 231 from the bending portion 130 to the first planar portion 110 is a first end, and an end portion of the first thermally conductive member 231 from the bending portion 130 to the second planar portion 120 is a second end. In the first direction X, a length d1 by which the first end of the first thermally conductive member 231 extends into the first planar portion 110 equals a length d2 by which the second end of the first thermally conductive member 231 extends into the second planar portion 120, so that the lengths of the first thermally conductive member 231 on two sides of the bending portion 130 are equal. Therefore, the stress bearing capacities of the first thermally conductive member 231 on the two sides of the bending portion 130 are equal, achieving more stable structure.

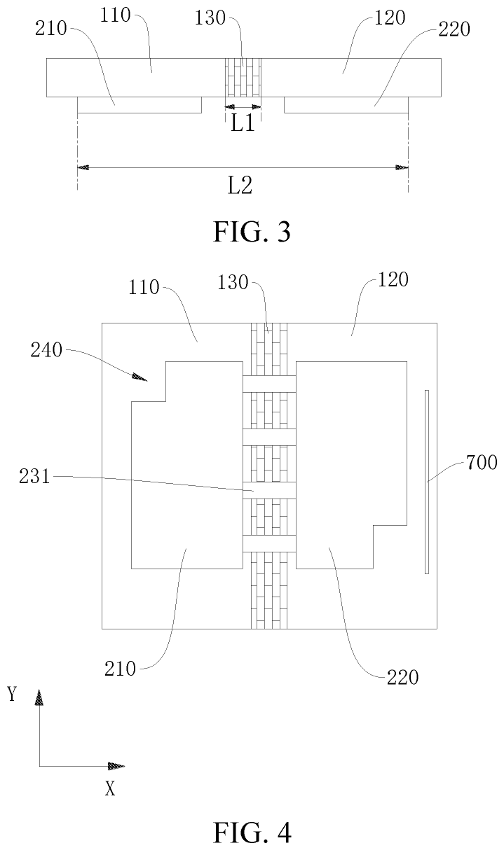

Referring to FIG. 3, in the foldable display back panel of the present disclosure, in the first direction X, the length L1 of the bending portion 130 accounts for 8% to 11% of a length L2 of the heat dissipation layer 200.

In the present embodiment, the length of the bending portion 130 may account for 8%, 9%, 10%, or 11% of the length of the heat dissipation layer 200. It is to be noted that, the length of the bending portion 130 may account for any value ranging from 8% to 11% of the length of the heat dissipation layer 200, which is not enumerated herein in the present embodiment.

In actual application, area ratios of the bending portion 130 to the first planar portion 110 and to the second planar portion 120 are adaptively adjusted according to a product size. Therefore, the bending portion 130 of a different product has a different length in the first direction. In the present embodiment, the length of the bending portion 130 in the first direction X is set to 8% to 11% of the length of the heat dissipation layer 200, so that the size of the heat dissipation layer 200 can vary with the size of the bending portion 130 (or vary with the product size), thereby achieving more efficient heat dissipation for a display module.

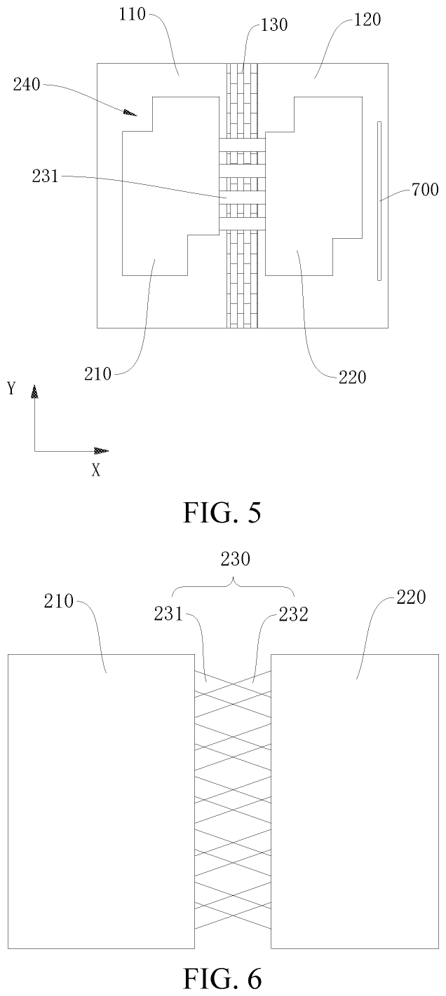

Referring to FIGS. 4 and 5, in the foldable display back panel of the present disclosure, at least one notch 240 is provided on the first heat dissipation portion 210 and/or the second heat dissipation portion 220. The notch 240 is located at an end corner of the corresponding heat dissipation portion.

In the present embodiment, the notch 240 is provided on the first heat dissipation portion 210 and/or the second heat dissipation portion 220, so that a space is reserved in the rigid support layer 100 to finally assemble the foldable display back panel with other parts, avoid space obstructions.

In the present embodiment, the notch 240 may be in a rectangular shape, a triangular shape, a circular shape, or other regular shapes or irregular shapes. The detailed shape of the notch 240 depends on a space required to be reserved for assembly, which is not limited in detail in the present disclosure.

In the present embodiment, as shown in FIG. 4, the first heat dissipation portion 210 and the second heat dissipation portion 220 are both in rectangular shapes. Each of the first heat dissipation portion 210 and the second heat dissipation portion has one notch 240. The two notches 240 are at diagonal positions on the heat dissipation layer 200.

In the present embodiment, as shown in FIG. 5, the first heat dissipation portion 210 and the second heat dissipation portion 220 are both in a stepped shape. Each of the first heat dissipation portion 210 and the second heat dissipation portion 220 has two notches 240. The two notches 240 are respectively at diagonal positions on the first heat dissipation portion 210 or the second heat dissipation portion 220. Therefore, the first heat dissipation portion 210 or the second heat dissipation portion 220 is in a stepped shape.

It is to be noted that, in the present embodiment, the sizes, the quantity, and the positions of the notches 240 depend on a space required to be reserved for assembling the rigid support layer 100, which are not limited in detail in the present embodiment.

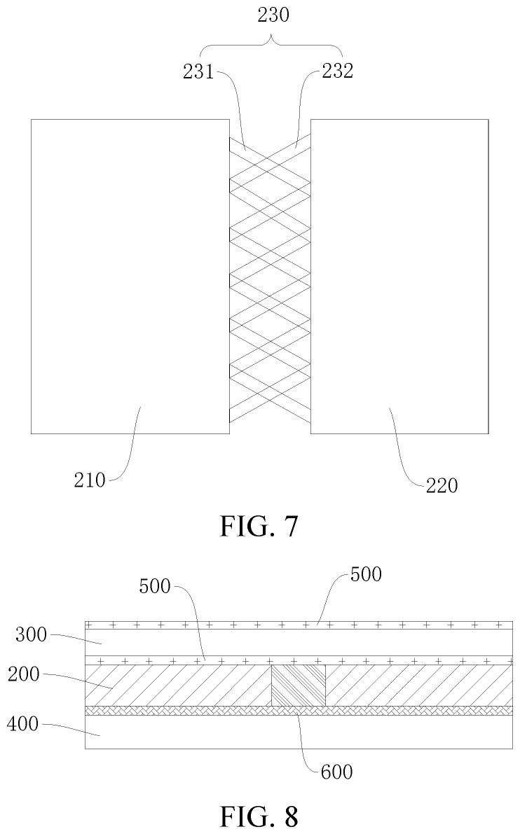

Referring to FIGS. 6 and 7, in the foldable display back panel of the present disclosure, the bridging portion 230 further includes a plurality of second thermally conductive members 232. The plurality of second thermally conductive members 232 are spaced apart from each other in parallel. The second thermally conductive members 232 are connected to the first heat dissipation portion 210 and the second heat dissipation portion 220. The first thermally conductive members 231 and the second thermally conductive members 232 intersect each other.

In the present embodiment, the plurality of second thermally conductive members 232 are spaced apart from each other, and the second thermally conductive members 232 and the first thermally conductive members 231 are caused to intersect each other, so that the plurality of first thermally conductive members 231 and the plurality of second thermally conductive members 232 form a net structure. In this way, the overall structural strength and the overall heat conducting performance of the bridging portion 230 are enhanced.

In the present embodiment, the first thermally conductive member 231 may be at an included angle with the first direction X. That is to say, the first end of the first thermally conductive member 231 is connected to the first heat dissipation portion 210, and the second end of the first thermally conductive member 231 obliquely extends to be connected to the second heat dissipation portion 220.

In the present embodiment, each of the second thermally conductive members 232 may also be at an included angle with the first direction X. That is to say, a first end of the second thermally conductive member 232 is connected to the first heat dissipation portion 210, and a second end of the second thermally conductive member 232 obliquely extends to be connected to the second heat dissipation portion 220.

In the present embodiment, as shown in FIG. 7, the first end of the first thermally conductive member 231 may be disposed to overlap the first end of the second thermally conductive member 232, and the second end of the first thermally conductive member 231 may be disposed to overlap the second end of the second thermally conductive member 232. In this way, the strength of the connection between the first thermally conductive member 231 and the second thermally conductive member 232 and the first heat dissipation portion 210 and the second heat dissipation portion 220 is enhanced.

In the present embodiment, the first thermally conductive member 231 and the second thermally conductive member 232 may be disposed at different layers. That is to say, the plurality of first thermally conductive members 231 are located in a first plane, and the plurality of second thermally conductive members 232 are located in a second plane. The first plane and the second plane are parallel to the bending portion 130.

In the present embodiment, the first thermally conductive members 231 and the second thermally conductive members 232 are connected by gluing or spot welding at the intersections.

In the present embodiment, the first thermally conductive members 231 and the second thermally conductive members 232 may be disposed at a same layer. For example, the first thermally conductive members 231 and the second thermally conductive members 232 are net structures made of one thermally conductive material by hollowing. Alternatively, the plurality of first thermally conductive members 231 and the plurality of second thermally conductive members 232 are formed as an intersected woven net structure by weaving, to enhance the bonding strength, the stability, and the heat conducting performance of the first thermally conductive members 231 and the second thermally conductive members 232.

Referring to FIG. 7, in the foldable display back panel of the present disclosure, the first thermally conductive members 231, the second thermally conductive members 232, the first heat dissipation portion 210, and the second heat dissipation portion 220 are integrally formed. In the present embodiment, the heat dissipation layer 200 may be directly formed by means of die cutting, simplifying the formation process of the heat dissipation layer 200, and improving the overall structural stability of the heat dissipation layer 200.

Referring to FIG. 8, in the foldable display back panel of the present disclosure, the foldable display back panel further includes a first protective layer 300 and a second protective layer 400 disposed on two sides of the heat dissipation layer 200. The first protective layer 300 and the second protective layer 400 are consecutively disposed on the heat dissipation layer 200 and cover the bridging portion 230.

In the present embodiment, the first protective layer 300 and the second protective layer 400 are disposed on the two sides of the heat dissipation layer 200, and the heat dissipation layer 200 is located between the two protective layers, so that the heat dissipation layer 200 is not easily broken by a relatively large bending stress. In this way, the heat conducting performance of the heat dissipation layer 200 is stably maintained. In addition, in the present embodiment, the first protective layer 300 and the second protective layer 400 are consecutively disposed and cover the bridging portion 230, so that the bridging portion 230 having relatively low structural strength can be well protected, and the first protective layer 300 and the second protective layer 400 can connect the first heat dissipation portion 210, the bridging portion 230, and the second heat dissipation portion 220 as a whole. In this way, the first heat dissipation portion 210, the bridging portion 230, and the second heat dissipation portion 220 are not easily broken and separated by dragging.

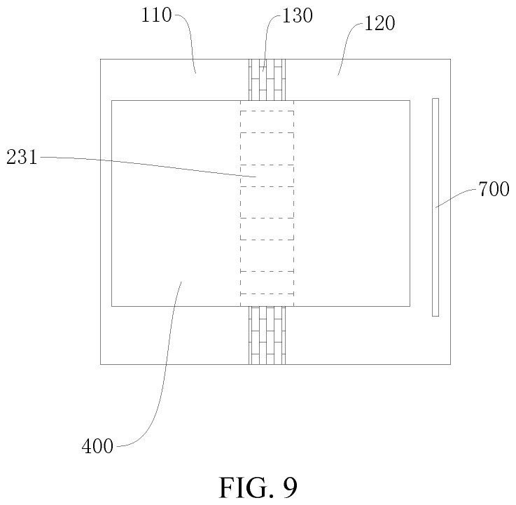

Referring to FIGS. 8 and 9, in the foldable display back panel of the present disclosure, the first protective layer 300 and the second protective layer 400 are elastic buffer layers. In the present embodiment, the elastic buffer layers may be made of a black thermoplastic polyurethane (TPU) elastomer rubber material, so that the first protective layer 300 and the second protective layer 400 have desirable elastic buffer capabilities to resist external collision, thereby protecting the heat dissipation layer 200 more effectively.

In the present embodiment, the first protective layer 300 is disposed between the rigid support layer 100 and the heat dissipation layer 200. Side surfaces of the first protective layer 300 in contact with the rigid support layer 100 and the heat dissipation layer 200 are coated with a first adhesive layer 500. In the present embodiment, the rigid support layer 100 is adhered to the heat dissipation layer 200 using the first adhesive layer 500, so that the heat dissipation layer 200 is firmly adhered to the rigid support layer 100. Therefore, heat on the rigid support layer 100 can be efficiently dissipated.

The second protective layer 400 is disposed on a side surface of the heat dissipation layer 200 away from the rigid support layer 100. A side surface of the second protective layer 400 in contact with the heat dissipation layer 200 is coated with a second adhesive layer 600. In the present embodiment, the second protective layer 400 is adhered to the heat dissipation layer 200 using the second adhesive layer 600, so that the bonding strength of second protective layer 400 and the heat dissipation layer 200 is relatively desirable, thereby achieving a more stable protection effect.

An embodiment of the present disclosure further provides a process for forming the foldable display back panel. The formation process includes:
providing a coiled heat dissipation layer 200 material, a rigid support layer 100, and two coiled black TPU materials;
performing die cutting on the coiled heat dissipation layer 200 material to obtain a coiled heat dissipation layer 200 material having a shape of the bridging portion 230;
coating two sides of a first coiled black TPU material with a first adhesive layer 500, and coating a side of a second coiled black TPU material with a second adhesive layer 600;
adhering one side of the first coiled black TPU material and the side of the second coiled black TPU material coated with the second adhesive layer 600 to two sides of a heat dissipation layer 200 respectively, to obtain a composite heat dissipation layer 200; and
adhering a side of the first coiled black TPU material in the composite heat dissipation layer 200 facing away from the heat dissipation layer 200 to the rigid support layer 100, to obtain the foldable display back panel.

An embodiment of the present disclosure further provides a display terminal. The display terminal includes a terminal body and the above foldable display back panel. The terminal body and the foldable display back panel are combined as a whole. In the present embodiment, the display terminal may include a mobile phone, a tablet computer, a notebook computer, an e-reader, and the like.

According to the embodiments of the present disclosure, the heat dissipation layer 200 is disposed on the rigid support layer 100 to improve the heat dissipation capability of the foldable display back panel. The bridging portion 230 of the heat dissipation layer 200 corresponds to the bending portion 130 of the rigid support layer 100. The bridging portion 230 includes the plurality of first thermally conductive members 231 spaced apart from each other and the plurality of second thermally conductive members 232 spaced apart from each other. Therefore, not only the first heat dissipation portion 210 and the second heat dissipation portion 220 of the heat dissipation layer 200 are connected as a whole, enhancing the heat conducting performance and the heat dissipation performance, but also the plurality of first thermally conductive members 231 and the plurality of second thermally conductive members 232 intersecting each other form a net structure easily bent without wrinkles and having relatively high structural strength, reducing the possibility of abnormal display. In this way, both relatively high heat dissipation performance and display quality are achieved.

The foldable display back panel and the display terminal provided in the embodiments of the present disclosure are described above in detail. Although the principles and implementations of the present disclosure are described by using specific examples in this specification, the descriptions of the foregoing embodiments are only intended to help understand the method and the core idea of the present disclosure. Meanwhile, a person skilled in the art may make modifications to the specific implementations and an application range according to the idea of the present disclosure. In conclusion, the content of this specification is not to be construed as a limitation to the present disclosure.

What is claimed is:

1. A foldable display back panel, comprising:
a rigid support layer comprising a first planar portion, a second planar portion, and a bending portion located between the first planar portion and the second planar portion; and
a heat dissipation layer disposed on the rigid support layer and comprising a first heat dissipation portion located on the first planar portion, a second heat dissipation portion located on the second planar portion, and a bridging portion located on the bending portion, wherein
the bridging portion comprises a plurality of first thermally conductive members spaced apart from each other and connected to the first heat dissipation portion and the second heat dissipation portion.

2. The foldable display back panel as claimed in claim 1, wherein the first thermally conductive members are disposed in a first direction.

3. The foldable display back panel as claimed in claim 2, wherein the plurality of first thermally conductive members are equidistantly arranged in a second direction.

4. The foldable display back panel as claimed in claim 3, wherein the second direction is an extending direction of the bending portion, and the first direction is perpendicular to the second direction.

5. The foldable display back panel as claimed in claim 4, wherein in the first direction, a length of each of the first thermally conductive members is greater than a length of the bending portion.

6. The foldable display back panel as claimed in claim 5, wherein in the first direction, the length of the bending portion accounts for 8% to 11% of a length of the heat dissipation layer.

7. The foldable display back panel as claimed in claim 1, wherein at least one notch is provided on the first heat dissipation portion or the second heat dissipation portion.

8. The foldable display back panel as claimed in claim 7, wherein the notch is located at an end corner of the corresponding heat dissipation portion.

9. The foldable display back panel as claimed in claim 1, wherein the bridging portion further comprises a plurality of second thermally conductive members.

10. The foldable display back panel as claimed in claim 9, wherein the plurality of second thermally conductive members are spaced apart from each other.

11. The foldable display back panel as claimed in claim 10, wherein the first thermally conductive members and the second thermally conductive members intersect each other.

12. The foldable display back panel as claimed in claim 9, wherein the first thermally conductive members, the second thermally conductive members, the first heat dissipation portion, and the second heat dissipation portion are integrally formed.

13. The foldable display back panel as claimed in claim 1, wherein the foldable display back panel further comprises a first protective layer and a second protective layer disposed on two sides of the heat dissipation layer.

14. The foldable display back panel as claimed in claim 13, wherein the first protective layer and the second protective layer are consecutively disposed on the heat dissipation layer and cover the bridging portion.

15. The foldable display back panel as claimed in claim 13, wherein the first protective layer and the second protective layer are elastic buffer layers.

16. The foldable display back panel as claimed in claim 15, wherein the first protective layer is disposed between the rigid support layer and the heat dissipation layer.

17. The foldable display back panel as claimed in claim 16, wherein side surfaces of the first protective layer in contact with the rigid support layer and the heat dissipation layer are coated with a first adhesive layer.

18. The foldable display back panel as claimed in claim 17, wherein the second protective layer is disposed on a side surface of the heat dissipation layer away from the rigid support layer.

19. The foldable display back panel as claimed in claim 18, wherein a side surface of the second protective layer in contact with the heat dissipation layer is coated with a second adhesive layer.

20. A display terminal, comprising a terminal body and the foldable display back panel as claimed in claim 1, wherein the terminal body and the foldable display back panel are combined as a whole.
